(19) United States
(12) Patent Application Publication
(10) Pub. No.: US 2002/0063338 A1
(43) Pub. Date: May 30, 2002

(54) Semiconductor device

(75) Inventors: Noboru Mikami, Tokyo (JP); Sei Tsunoda, Tokyo (JP); Hideharu Nobutoki, Tokyo (JP)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(73) Assignee: MITSUBISHI DENKI KABUSHIKI KAISHA, TOKYO (JP)

(21) Appl. No.: 10/011,982

(22) Filed: Dec. 11, 2001

(51) Int. Cl. H01L 23/48

(52) U.S. Cl. 257/762; 257/774

(57) ABSTRACT

A semiconductor device comprises a first insulating layer having a first copper wiring, a second insulating layer having a via of copper communicating with the first copper wiring, a third insulating layer having a second copper communicating with the via, and wherein either of the insulating layers is made of a material containing boron and nitrogen as a main component. Diffusion of copper into the insulating layer is prevented and, at the same time, wiring capacitance is reduced so that a high speed operation of the semiconductor device is enabled.

### BACKGROUND OF THE INVENTION

The present invention relates to a semiconductor device and a manufacturing method thereof, and particularly relates to a semiconductor device having a conductive layer made of copper and a manufacturing method thereof.

A request for a high degree of integration and a high speed operation in a semiconductor device has been increasingly built up and in order to meet such a request, studies have been conducted on material of a conductive layer, that is, a wiring material with a lower resistance, which can replace a prior art aluminum alloy; and on material of an insulating layer with a lower dielectric constant, which can replace a prior art silicon oxide. Especially in a case where the minimum structural dimension of a semiconductor device is less than a value of the order of 0.18 μm, the above materials become necessary in configuration of the semiconductor device, which is described in, for example, a document entitled “Recent Development in Cu Wiring Technology” edited by S. Shingubara, N. Awaya, K. Ueno and N. Misawa, and published by Realize Co. (hereinafter referred to as document 1).

FIG. 4 is a sectional view showing copper wirings of a two layer structure described in the above document 1. In the figure, a reference numeral 1 indicates a silicon substrate and a reference numeral 2 indicates a first insulating layer, and the first insulating layer 2 is made of silicon oxide with a dielectric constant of 4.2 or fluorine-containing silicon oxide with a dielectric constant ranging from 3.2 to 3.5; and in addition, studies have been conducted on applicability, as alternates, of a silicon-containing inorganic material, an organic polymeric material, a fluorine-containing amorphous carbon film, a porous silicon oxide film or the like, all with a dielectric constant of 2.8 or less. A trench 3 in the pattern of a first wiring is formed in the first insulating layer 2. A reference numeral 4 indicates a first conductive film provided as a barrier metal to coat the bottom and side surfaces of the trench 3 therewith and to thereby prevent diffusion of copper therethrough, and as a material of the first conductive film 4, there is used titanium nitride (TiN), tantalum nitride (TaN), tungsten nitride (WN) or the like, or a three-component material obtained by adding silicon to each of these nitrides or the like. A reference numeral 5 indicates a first copper conductive layer to fill the trench 3 which is coated with the first conductive film 4, and a reference numeral 6 indicates a first insulating film having a diffusion preventive function against copper, which is made of silicon nitride. A reference numeral 7 indicates a second insulating layer, which is made of a material similar to that of the first insulating layer 2. A first hole 8 is formed in the first insulating film 6 and the second insulating layer 7 therethrough and the bottom and side surfaces of the first hole 8 are coated with a second conductive film 9 having a diffusion preventive function and contacting the first copper conductive layer 5. The first hole 8 which is coated with the second conductive film 9 is filled with a second copper conductive layer 10. Furthermore, a trench 12 in a pattern of a second wiring is formed in the second insulating layer 7. The inner surface of the trench 12 is coated with a third conductive film 11 having a diffusion preventive function against copper. The trench 12 whose inner surface is coated with the third conductive film 11 is filled with a third copper conductive layer 13. The second and third conductive films 9 and 11 are made of a material similar to that of the first conductive film 4. A top surface of the third copper conductive layer 13 is covered with a second insulating film 14 made of silicon nitride having a diffusion preventive function against copper. As described above, the first and third copper conductive layers 5 and 13 constitute wirings in the lower and the upper layers respectively, and the second copper conductive layer 10 electrically connects the wirings in the upper and the lower layers therebetween. While the wiring of a two layer structure is shown in FIG. 4, this structure is repeatedly stacked to form a multi-layer structure.

An wiring structure of FIG. 4 is formed through so-called Damascene process, which will be described below. The trench 3 in the pattern of an interconnect wiring is formed in the first insulating layer 2, and the first conductive film 4, serving as a barrier metal, is formed on the inner surface of the trench 3. Then, a copper layer is formed to be filled in the trench 3 and forms the first copper conductive layer 5. In forming film of the barrier metal and layer of copper, the barrier metal and copper are also formed on regions of the surface of the first insulating layer 2 other than the trench 3; therefore, such unnecessary barrier metal and copper are removed by CMP (chemical mechanical polishing) leaving the barrier metal and copper only in the trench 3 to form the first copper conductive layer 5. In such a process, the copper wiring in the lower layer is formed in the trench 3 with the bottom and side surfaces thereof coated with the first conductive film 4. Then, the silicon nitride film 6 and the second insulating layer 7 are sequentially stacked on the first insulating layer 2. The trench 12 in the pattern of the second wiring and the first hole 8 extending to the first conductive layer 5 are formed in the silicon nitride film 6 and the second insulating layer 7 therethrough. The second and third conductive films 9 and 11 as the barrier metal are formed on the inner surfaces of the trench 12 and the first hole 8, and a copper layer is further formed in the trench 12 and the first hole 8 to fill, followed by removal of unnecessary copper and the barrier metal on the second insulating layer 7 using CMP to thereby form the wiring in the upper layer. Thereafter, the second insulating film 14 is formed.

In a case where a polymeric material or a porous silicon oxide, both with a low dielectric constant, is used as a material of an insulating layer of a semiconductor device, the materials are poorer in thermal conductivity, as compared with silicon oxide which was used in a prior art practice, to call for increase in temperature of a semiconductor device due to heat generation in an wiring, so that a concern arises about deterioration in reliability of wiring and a device.

FIG. 5 shows an wiring structure in which two kinds of materials are used for insulating layers in order to solve the problem associated with poor thermal conductivity. A material with a low dielectric constant such as a polymeric material is used as a material of insulating layers 15 and 16 in which wirings, that are the first copper conductive layer 5 and the third copper conductive layer 13, are formed, while silicon oxide having a good thermal conductivity is used as a material of an insulating layer 18 in which the hole 8 is formed and besides, as a material of an insulating layer 17 placed between the first copper wiring 5 and the substrate 1 as was in a prior art practice, thereby suppressing deterioration in thermal conductivity as a whole. Such an wiring structure is described in, for example, W. Y. Shih, M. C. Chang, R. H. Havemann and J. Levine: 1997 Symposium on VLSI Technology Digest, p 83 (hereinafter referred to as document 2).

It is described in the above document 1 that wiring has been miniaturized in feature size and layout, and wiring length has increased due to increase in chip area in company with development toward high degree of integration in integrated circuit of a semiconductor device, which has resulted in a propagation delay of a signal on an wiring, which has been growing to a major cause hindering advent of a high speed device. In order to solve such a problem, a necessity arises for use of a low resistance wiring material for reduction in wiring resistance and use of an insulating layer with a low dielectric constant for reduction in electrostatic capacitance between wirings, that is an wiring capacitance. As an wiring material for this purpose, copper is at the first stage in the application as substitute for aluminum alloy used in a prior art practice. On the other hand, as an insulating layer for this purpose, fluorine-containing silicon oxide with a dielectric constant ranging from 3.2 to 3.5, that is so-called SiOF, is also at the starting stage in its use as substitute for silicon oxide with a dielectric constant of 4.2.

Since copper easily diffuses into insulating layers under application of an electric field, a necessity exists for coating the surface of an copper wiring with a diffusion preventive film when copper is used as an wiring material. Therefore, the lower and side surfaces of a copper wiring is coated with a conductive barrier metal, while the top surface thereof is coated with an insulating silicon nitride. A dielectric constant of the silicon nitride film is of the order of 7, resulting in increase in wiring capacitance. Moreover, even in a case where above insulating layer having a low dielectric constant is used, conventional silicon oxide-having a good thermal conductivity is used as a material of a layer through which a via hole connects the upper and lower wirings (e.g. the insulating layer 18 in FIG. 5) in order to avoid reduction in reliability as was in a prior art practice. Hence, sufficient reduction in wiring capacitance cannot be achieved even by use of an insulating layer of a low dielectric constant. Thus, a problem has been present since increase in wiring capacitance causes a propagation delay of a signal to thereby suppress a high speed in operation of a semiconductor device.

Furthermore, another problem has been present since, while a copper wiring is coated with a conductive film of a barrier metal in order to prevent copper from diffusing into the insulating layers, a resistance of the barrier metal is much higher than that of copper, an increase occurs in resistance value of the wiring as a whole, leading to suppression of a high speed in operation of a semiconductor device.

The present invention has been made in order to solve the above problems and it is an object of the present invention to provide a semiconductor device capable of performing a high speed operation by use of a material containing boron nitride as a main component, which has a diffusion preventive function against copper, as an insulating layer or an insulating film in a copper wiring structure.

### SUMMARY OF THE INVENTION

A semiconductor device according to the first aspect of the present invention comprises; a first insulating layer having a first trench and being formed on a surface of a semiconductor substrate, a first copper conductive layer formed so as to fill the first trench, a second insulating layer having a hole communicating with the first copper conductive layer, a second copper conductive layer filling the hole so as to contact with the first copper conductive layer, a third insulating layer being formed on the second insulating layer and having a trench communicating with the second copper conductive layer, and a third copper conductive layer contacting the second copper conductive layer and being formed so as to fill the trench formed in the third insulating layer, wherein either the first insulating layer or the second insulating layer or the third insulating layer is made of a material containing boron nitride as a main component.

A semiconductor device according to the second aspect of the present invention comprises; a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer having a second hole communicating with the first hole, a second copper conductive layer filling the second hole so as to contact with the first copper conductive layer, a third insulating layer being formed on the second insulating layer and having a trench communicating with the second copper conductive layer, and a third copper conductive layer contacting with the second copper conductive layer and being formed so as to fill the second trench formed in the third insulating layer, wherein the insulating film is made of a material containing boron nitride as a main component.

A semiconductor device according to the third aspect of the present invention comprises; a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer in which a second hole and a second trench communicating with the first hole are formed, a second copper conductive layer filling the second hole so as to contact with the first copper conductive layer, and a third copper conductive layer contacting with the second copper conductive layer and formed so as to fill the second trench formed in the second insulating layer, wherein the insulating film is made of a material containing boron nitride as a main component.

The fourth aspect of the present invention is directed to a semiconductor device according to the first, second or third aspect of the present invention wherein the insulating layer or the insulating film made of a material containing boron nitride as a main component includes hydrogen.

The fifth aspect of the present invention is directed to a semiconductor device according to the first, second or third aspect of the present invention wherein the insulating layer or the insulating film made of a material containing boron nitride as a main component includes carbon or fluorine.

The sixth aspect of the present invention is directed to a semiconductor device according to the first, second or third aspect of the present invention wherein the insulating layer or the insulating film made of a material containing boron nitride as a main component is amorphous.

The seventh aspect of the present invention is directed to a semiconductor device according to the first, second or third aspect of the present invention wherein the insulating layer or the insulating film made of a material containing boron nitride as a main component is in a state of a mixture of microcrystals and an amorphous structure.

According to the present invention, a semiconductor device comprises a first insulating layer having a first trench and formed on a surface of a semiconductor substrate, a first copper conductive layer formed so as to fill the first trench, a second insulating layer having a hole communicating with the first copper conductive layer, a second copper conductive layer filling the hole so as to contact the first copper conductive layer, a third insulating layer formed on the second insulating layer and having a second trench communicating with the second copper conductive layer, and a third copper conductive layer contacting the second copper conductive layer and formed so as to fill the second trench formed in the third insulating layer. At least one of the first insulating layer, the second insulating layer and the third insulating layer is made of a material containing boron and nitrogen, therefore, not only diffusion of copper from a copper conductive layer can be prevented, but also an wiring capacitance can be reduced as compared with a case of a prior art semiconductor device, thereby enabling a high speed operation of the semiconductor device.

According to the present invention, a semiconductor device also comprises a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer having a second hole communicating with the first hole, a second copper conductive layer filling the second hole so as to contact with the first copper conductive layer, a third insulating layer being formed on the second insulating layer and having a trench communicating with the second copper conductive layer, and a third copper conductive layer contacting with the second copper conductive layer and being formed so as to fill the second trench formed in the third insulating layer. The insulating film is made of a material containing boron and nitrogen, therefore, not only diffusion of copper from a copper conductive layer can be prevented, but also an wiring capacitance can be reduced without deteriorating a thermal conductivity as compared with a prior art semiconductor device, thereby enabling a high speed operation and high reliability of the semiconductor device.

According to the present invention, a semiconductor device also comprises a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer in which a second hole and a second trench communicating with the first hole are formed, a second copper conductive layer filling the second hole so as to contact the first copper conductive layer, and a third copper conductive layer contacting with the second copper conductive layer and formed so as to fill the second trench formed in the second insulating layer. The insulating film is made of a material containing boron and nitrogen, therefore, not only diffusion of copper from a copper conductive layer can be prevented, but also an wiring capacitance can be reduced as compared with a case of a prior art semiconductor device, thereby enabling a high speed operation of the semiconductor device.

Furthermore, by adding carbon or fluorine to an insulating layer or an insulating film containing boron and nitrogen, there can be obtained the insulating layer or the insulating film of much lower dielectric constant, which enables further reduction in wiring capacitance.

Moreover, by forming at least one of insulating layers containing neither boron nor nitrogen from silicon oxide, good thermal conductivity can be realized to obtain a semiconductor device with high reliability.

Furthermore, by forming at least one of insulating layers containing neither boron nor nitrogen from poly(aryl ether), further reduction in wiring capacitance can be realized to obtain a semiconductor device with a higher speed operation.

These and other objects, advantages and features of the present invention will become more apparent from the following description and the accompanying drawings.

### BRIEF DESCRIPTION OF THE DRAWINGS

FIG. 1 is a sectional view showing a semiconductor device according to Embodiment 1 of the present invention;

FIG. 2 is a sectional view showing a semiconductor device according to Embodiment 2 of the present invention;

FIG. 3(a) is a sectional view showing a semiconductor device according to Embodiment 3 of the present invention and FIG. 3(b) is a sectional view showing another semiconductor device according to Embodiment 3 of the present invention;

FIG. 4 is a sectional view showing a prior art copper wiring semiconductor device; and

FIG. 5 is a sectional view showing another prior art copper wiring semiconductor device.

### DETAILED DESCRIPTION

A semiconductor device of the present invention comprises; a first insulating layer having a first trench and formed on a surface of a semiconductor substrate, a first copper conductive layer formed so as to fill the first trench, a second insulating layer having a hole communicating with the first copper conductive layer, a second copper conductive layer filling the hole so as to contact the first copper conductive layer, a third insulating layer formed on the second insulating layer and having a second trench communicating with the second copper conductive layer, and a third copper conductive layer contacting the second copper conductive layer and formed so as to fill the second trench formed in the third insulating layer, wherein at least one of the first insulating layer, the second insulating layer and the third insulating layer is made of a material containing boron nitride as a main component.

A semiconductor device of the present invention also comprises; a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer having a second hole communicating with the first hole, a second copper conductive layer filling the first and second holes so as to contact the first copper conductive layer, a third insulating layer formed on the second insulating layer and having a second trench communicating with the second copper conductive layer, and a third copper conductive layer contacting the second copper conductive layer and formed so as to fill the second trench formed in the third insulating layer, wherein the insulating film is made of a material containing boron nitride as a main component.

A semiconductor device of the present invention also comprises; a first insulating layer having a first trench and formed on a surface of a semiconductor substrate, a first copper conductive layer formed so as to fill the first trench, an insulating film having a first hole communicating with the first copper conductive layer and with which the first copper conductive layer and the first insulating layer are coated, a second insulating layer in which a second hole and a second trench communicating with the first hole are formed, a second copper conductive layer filling the second hole so as to contact the first copper conductive layer, and a third copper conductive layer, contacting the second copper conductive layer, and formed so as to fill the second trench formed in the second insulating layer, wherein the insulating film is made of a material containing boron nitride as a main component.

A layer or film made of a material containing boron nitride as a main component is formed by procedures described in the following articles such as S. V. Nguyen, T. Nguyen, H. Treichel and O. Spindler, J. Electrochem. Soc., Vol. 141, No. 6, p 1633 (1994); W. F. Kane, S. A. Cohen, J. P. Hummel and B. Luther, J. Electrochem. Soc., Vol. 144, No. 2, p 658 (1997); and M. Maeda and T. Makino, Japanese Journal of Applied Physics, Vol. 26, No. 5, p 660 (1987). That is, the layer or film can be obtained through a condensation reaction of a mixture of diborane (B₂H₆) and ammonia (NH₃) or a mixture of borazine (B₃H₃N₆) and nitrogen (N₂) as a raw material in a chemical vapor deposition method (CVD method). According to description in the above articles, a dielectric constant of a layer or film thus formed and containing boron and nitrogen, that is made of boron nitride as a main component, ranges from 3 to 5 depending on a film forming condition.

In a semiconductor device of the present invention, an wiring capacitance can be reduced since there is used an insulating layer or an insulating film made of a material containing boron nitride as a main component, which is a material with a low dielectric constant, instead of an insulating layer or an insulating film made of oxide silicon or silicon nitride. Furthermore, by adding carbon (C) or fluorine (F) to boron nitride, an insulating layer or an insulating film with a much lower dielectric constant, e.g. dielectric constant of 2.0 to 1.5, can be obtained. Moreover, by using boron nitride, which has a diffusion preventive function against copper, as a main component of a material of an insulating layer or an insulating film, an wiring with a low resistance can be achieved without providing a barrier metal film at a contact portion between copper and the insulating layer or the insulating film. In addition, since boron nitride has good thermal conductivity, heat at the wirings is easily dissipated so that temperature as welll as resistance thereof are prevented from increasing. By reduction and suppression in capacitance and resistance of wiring, a semiconductor device can be operated at high speed.

Embodiment 1

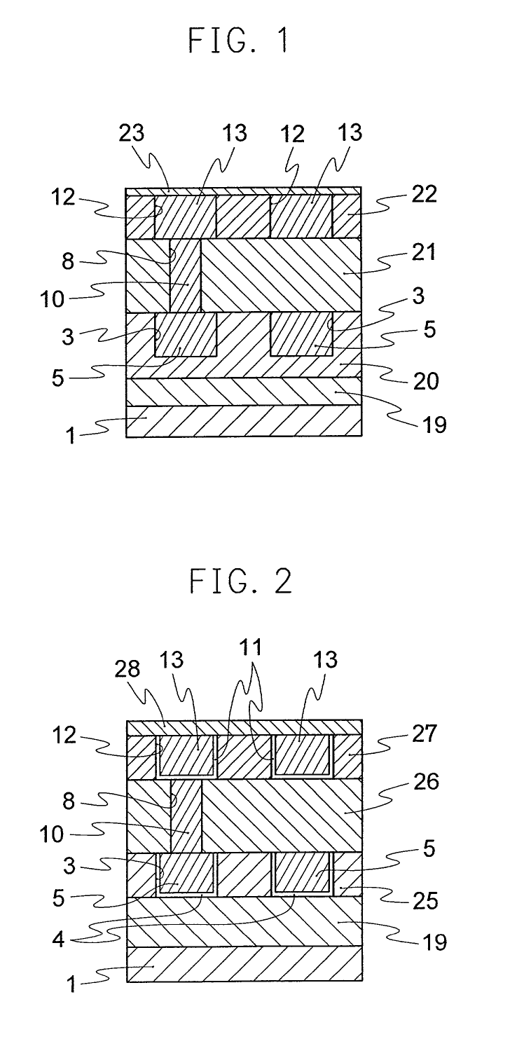

FIG. 1 is a sectional view of a semiconductor device according to a first embodiment of the present invention. In the figure, a reference numeral 1 indicates a semiconductor substrate made of silicon, and a reference numeral 19 indicates an insulating layer made of silicon oxide. However, the insulating layer 19 might be omitted. A reference numeral 20 indicates an insulating layer formed on the insulating layer 19, having a thickness of 0.3 μm, and made of amorphous boron nitride containing a great amount of hydrogen. In the insulating layer 20, there is formed a trench 3 in a pattern of a first wiring having a width of 0.2 μm and a depth of 0.2 μm. A reference numeral 5 indicates a first copper conductive layer filling the trench 3. A reference numeral 21 indicates an insulating layer, formed on the insulating layer 20 and the first copper conductive layer 5, having a thickness of 0.5 μm, made of boron nitride in a state of a mixture of hexagonal microcrystals and an amorphous structure, and with a small content of hydrogen. In the insulating layer 21, there is formed a hole 8 having a diameter of 0.15 μm and extending to the first copper conductive layer 5, and the hole 8 is filled with copper to form a second copper conductive layer 10 so as to contact the first copper conductive layer 5. A reference numeral 22 indicates an insulating layer formed on the insulating layer 21 and is of the same composition as that of the insulating layer 20 and has a thickness of 0.2 μm. In the insulating layer 22, there is formed a trench 12 having a depth of 0.2 μm, and in a pattern of a second wiring, wherein the bottom surface thereof extends to the insulating layer 21 and the trench 12 are filled with copper to form a third copper conductive layer 13. A reference numeral 23 indicates an insulating film, formed on the insulating layer 22 and the third copper conductive layer 13, and of the same composition as that of the insulating layer 21.

A semiconductor device of such an wiring structure is fabricated this way, for example. First of all, the insulating layers 19 and 20 are formed on the semiconductor substrate 1 and the trench 3 is formed in the insulating layer 20 by etching. Thereafter, the copper conductive layer 5 is formed and the conductive layer 5 formed on regions other than the trench 3 is removed by CMP. The insulating film 21 is then formed thereon and the hole 8 is formed into the insulating film 21 by etching. The hole 8 is filled with the second copper conductive layer 10 and the copper on regions other than the hole 8 is removed by CMP. In succession thereto, the insulating layer 22 is formed thereon and the trench 12 is formed into the insulating film 22, followed by formation of the third copper conductive layer 13. Copper formed on regions other than the trench 12 is removed by CMP, followed by formation of the insulating film 23 thereon.

Note that an alternative process in which the insulating layer 22 is formed directly after formation of the insulating layer 21 is also possible. In this alternative process, a technique so-called Dual Damascene is employed so that the hole 8 and the trench 12 are formed in a continuous manner and filled with the respective copper conductive layers 10 and 13 at one time. In the so-called Dual Damascene process, more specifically, the trench 12 at the left side of FIG. 1 is firstly formed by etching. Thereafter and succeedingly, the trench 12 at the right side of FIG. 1 and the hole 8 at the left side of FIG. 1 are formed by etching, and at this time, the trench 12 at the left side of FIG. 1 is also etched and slightly widened. Afterward, copper is filled into the hole 8 as well as the trenches 12 to form the second copper conductive layer 10 and the third copper conductive layer 13 at one time. Unnecessary copper formed on the upper surface of the insulating layer 22 is removed by CMP and the insulating film 23 is formed thereon.

In the semiconductor device fabricated in such a way, all of the copper conductive layers, that is the first copper conductive layer 5, the second copper conductive layer 10 and the third copper conductive layer 13 are surrounded by the respective insulating layers 20, 21 and 22, and the insulating film 23, all made of a material containing boron nitride as a main component. Therefore, dissimilar to the prior art semiconductor device shown in FIG. 5, copper diffusion from all of the conductive layers can be prevented from occurring without providing a barrier metal film or an insulating film between insulating layers. That is, an wiring capacitance can be reduced while preventing copper diffusion.

Furthermore, the insulating layers 20 and 22 are made of boron nitride with a large content of hydrogen (e.g. B₃N₃Hₓ: x>3.0) and have a dielectric constant of 3.2. The insulating layers 21 and 23 are made of boron nitride with a small content of hydrogen (e.g. B₃N₃Hₓ: 0<x<3.0) and have a dielectric constant of 4.0. In such a way, the insulating layers 20, 21, 22 and the insulating film 23 are made of materials of a low dielectric constant and among them, the insulating layer 21 and the insulating film 23 are made of a material with a relatively large thermal conductivity; thereby enabling reduction in wiring capacitance of a semiconductor device without a loss of reliability. Moreover, as described above, since no barrier metal film is required, an wiring resistance can be reduced as compared with the prior art semiconductor device shown in FIG. 5. By reduction in wiring capacitance and resistance, a high speed operation of a semiconductor device can be ensured.

Embodiment 2

FIG. 2 is a sectional view of a semiconductor device according to a second embodiment of the present invention. An insulating layer 19 made of silicon oxide is formed on a silicon semiconductor substrate 1. An insulating layer 25 having a thickness of 0.2 μm and made of poly(aryl ether) such as poly(arylene ether) is formed on the insulating layer 19. In the insulating layer 25, there is formed a trench 3 in a pattern of a first wiring, having a width of 0.2 μm and having a depth of 0.2 μm. A first conductive film (barrier metal film) 4 having a diffusion preventive function is formed so as to coat the inner surface of the trench 3 therewith. The barrier metal film 4 is made of tantalum nitride and has a thickness ranging from 10 nm to 20 nm. The interior of the trench 3 whose inner surface is coated with the barrier metal film 4 is filled with copper to form a first copper conductive layer 5. An insulating layer 26, made of boron nitride constituted of a mixture of hexagonal microcrystals and an amorphous structure, and having a thickness of 0.5 μm is formed on the insulating layer 25 and the first copper conductive layer 5. A hole 8 having a diameter of 0.15 μm and extending to the first copper conductive layer 5 is formed in the insulating layer 26. In the hole 8, a second copper conductive layer 10 is formed by filling the hole 8 with copper so as to contact the first copper conductive layer 5.

An insulating layer 27 of the same composition as that of the insulating layer 25 and having a thickness of 0.2 μm is formed on the insulating layer 26. A trench 12 in the pattern of a second wiring, having a depth of 0.2 μm and extending to the insulating layer 26 at its bottom, is formed in the insulating layer 27. A second conductive film (barrier metal film) 11 having a diffusion preventive function against copper is formed so as to coat the inner surface of the trench 12 therewith. The barrier metal film 11 has the same composition and the same thickness as those of the barrier metal film 4. The interior of the trench 12 whose inner surface is coated with the barrier metal film 11 is filled with copper to form a third copper conductive layer 13. An insulating film 28 of the same composition as that of the insulating layer 26 is formed on the insulating layer 27 and the third copper conductive layer 13.

A semiconductor device of such an wiring structure is fabricated this way, for example. The insulating layers 19 and 25 are formed on the semiconductor substrate 1 and the trench 3 is formed in the insulating film 25 by etching. Thereafter, the barrier metal film 4 made of tantalum nitride and the conductive layer 5 made of copper are formed in the trench 3, and the barrier metal film 4 and the conductive layer 5 formed on regions other than the trench 3 are removed by CMP. Then, the insulating layer 26 is formed thereon, followed by etching to form the hole 8 therein. The hole 8 is filled with the second copper conductive layer 10 and copper formed on regions other than the hole 8 is removed by CMP. In succession, the insulating layer 27 is formed thereon, followed by etching to form the trench 12. Thereafter, the barrier metal film 11 and the third copper conductive layer 13 are formed in the trench 13, and the barrier metal film 11 and the copper conductive layer 13 formed on regions other than the trench 12 are removed by CMP. Finally, the insulating film 28 is formed thereon.

In a semiconductor device fabricated in such a way, the first copper conductive layer 5 contacts with the barrier metal film 4 and the insulating layer 26, and the third copper layer 13 contacts with the barrier metal film 11 and the insulating layer 28. Further, the second copper conductive layer 10 contacts with the barrier metal 11 and the insulating layer 26. As described above, since the insulating layer 26 and the insulating film 28 are made of a material containing boron nitride having a diffusion preventive function against copper, as a main component, diffusion of copper from all of the conductive layers can be prevented from occurring. Moreover, the insulating layers 25 and 27 made of poly(aryl ether) have a dielectric constant as low as 2.8 and further, the insulating layers 26 and 28 made of boron nitride have a dielectric constant of 4.0. Therefore, as compared with a prior art semiconductor device shown in FIG. 5 in which silicon oxide is used for the insulating layer 18, reduction in wiring capacitance is enabled in the semiconductor device of this embodiment, thereby enabling a high speed operation of the semiconductor device of this embodiment to be realized.

Moreover, since boron nitride is used for the insulating layer 26 in this embodiment, the insulating film 6 and the barrier metal film 9 in the prior art semiconductor device shown FIG. 5 is unnecessary. Therefore, further reductions in wiring capacitance and in wiring resistance are achieved. Furthermore, the boron nitride insulating layer 26 in the present embodiment has better thermal conductivity than the silicon oxide insulating layer 18 of FIG. 5. Therefore, temperature of wiring is suppressed to maintain resistance of wiring lower so that a semiconductor device of high speed operation can be obtained from this point.

Embodiment 3

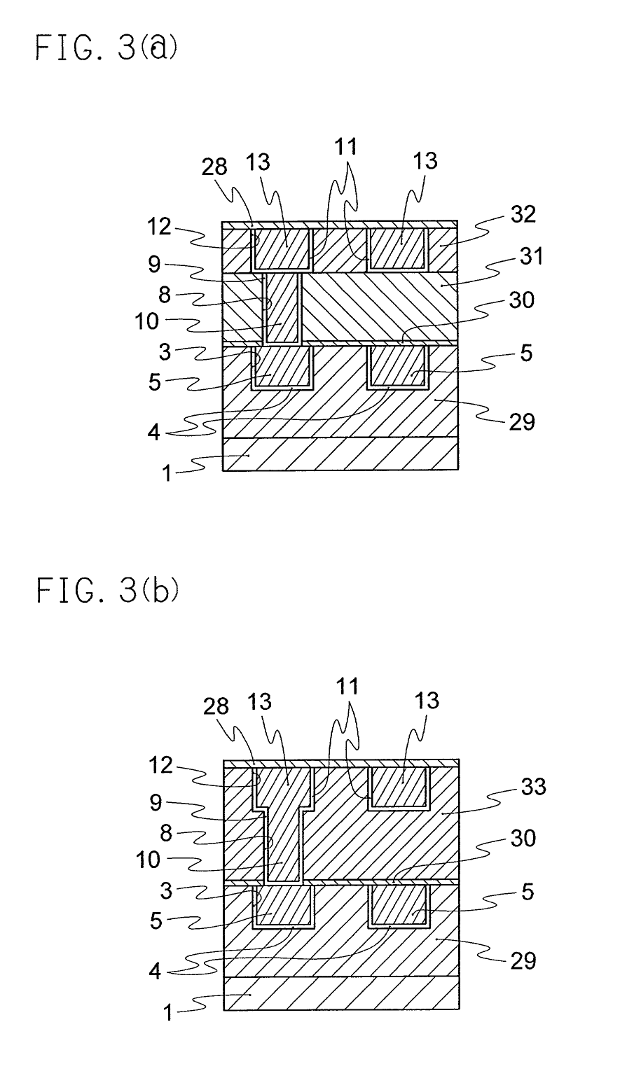

FIG. 3(a) is a sectional view of a semiconductor device according to a third embodiment of the present invention. An insulating layer 29 made of silicon oxide is formed on a semiconductor substrate 1 made of silicon. In the insulating layer 29, there is formed a trench 3 in a pattern of a first wiring having a width of 0.2 μm and a depth of 0.2 μm. A first conductive film (barrier metal film) 4 having a diffusion preventive function is formed in the trench 3 so as to coat the inner surfaces of the trench 3 therewith. The barrier metal film 4 is made of tantalum nitride and has a thickness ranging from 10 nm to 20 nm. The interiors of the trench 3 whose inner surfaces are coated with the barrier metal film 4 are filled with copper to form a first conductive layer 5. An insulating film 30, having a thickness of 0.05 μm and made of boron nitride in a state of a mixture of hexagonal microcrystals and an amorphous structure, is formed on the insulating layer 29 and the first copper conductive layer 5. An insulating layer 31 made of silicon oxide is formed on the insulating film 30. A hole 8 having a diameter of 0.15 μm is formed through the insulating film 30 and the insulating layer 31 so as to extend to the first copper conductive layer 5. A second conductive film (barrier metal films) 9 made of tantalum nitride having a diffusion preventive function against copper is formed so as to coat the inner surfaces of the hole 8. The interior of the hole 3 whose inner surfaces are coated with the barrier metal film 9 is filled with copper to form a second conductive layer 10. On the insulating layer 31, furthermore, a insulating layer 32 of the similar material as that of the insulating layer 31 is formed. A trench 12 in a pattern of a second wiring and having a depth of 0.2 μm is formed in the insulating layer 32. A third conductive film (barrier metal films) 11 having a diffusion preventive function against copper is formed so as to coat the inner surfaces of the trench 12 therewith. The interior of the trench 12 whose inner surfaces are coated with the barrier metal film 11 is filled with copper to form a third copper conductive layer 13. A insulating film 28 of the same composition as that of the insulating layer 30 is formed on the insulating layer 32 and the third copper conductive layer 13.

A semiconductor device of such an wiring structure is fabricated this way, for example. The insulating layer 29 is formed on the semiconductor substrate 1 and the trench 3 is formed by etching in the insulating layer 29. Thereafter, the barrier metal film 4 and the copper conductive layer 5 are formed on the inner surfaces of the trench 3, and the barrier metal film 4 and the conductive layer 5 formed on regions other than the trench 3 are removed by CMP. Then, the insulating film 30 is formed thereon and further the insulating layer 31 is formed thereon. In succession, the insulating layer 31 and the insulating film 30 are etched to form the hole 8. The barrier metal film 9 is formed on the inner surfaces of the hole 8, and the hole 8 is filled with copper to form the second copper conductive layer 10. The barrier metal film 9 and the copper conductive layer 10 formed on regions other than the hole 8 are removed by CMP. Then, the insulating layer 32 is formed thereon and the insulating layer 32 is etched to form the trench 12. The barrier metal film 11 is formed on the inner surfaces of the trench 12, and the trench 12 is filled with copper to form the third copper conductive layer 13. The barrier metal film 11 and the copper conductive layer 13 formed on regions other than the trench 12 are removed by CMP, followed by formation of the insulating film 28.

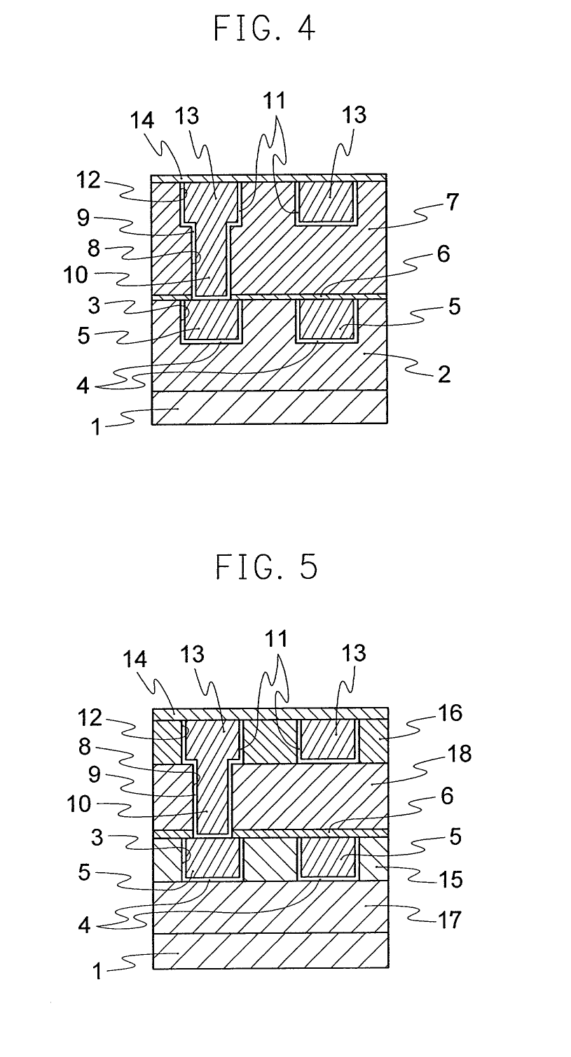

In a semiconductor device fabricated in such a way, the first, second and third copper conductive layers 5, 10 and 13 contact with the respective barrier metal films 4, 9 and 11, and further, in the corresponding manner, the insulating films 30 and 28. Therefore, diffusion of copper from all of the copper conductive layers 5, 10 and 13 can be prevented from occurring. In the semiconductor device of this embodiment, since a dielectric constant of the insulating films 30 and 28 is 4.0, an wiring capacitance can be reduced as compared with a prior art wiring structure of FIG. 4 in which silicon nitride insulating films having a dielectric constant of 7.0 are used, thereby enabling a high speed operation of the semiconductor device to be realized.

FIG. 3(b) is a sectional view of another semiconductor device according to the present embodiment. As shown in FIG. 3(b), an insulating layer 33 made of silicon oxide is formed on the insulating film 30 replacing the insulating layers 31 and 32 of FIG. 3(a). A hole 8 is formed through the insulating film 30 and the insulating layer 33 so as to extend to the first copper conductive layer 5. Furthermore, a trench 12 in a pattern of a second wiring is formed in the insulating layer 33 together with the hole 8. The second and third conductive films (barrier metal films) 9 and 11 made of tantalum nitride having a diffusion preventive function against copper are formed so as to coat the inner surfaces of the hole 8 and the trench 12 therewith. The interior of the hole 8 and the trench 12 whose inner surfaces are coated with the respective barrier metal films 9 and 11 are filled with copper to form a second copper conductive layer 10 and a third copper conductive layer 13. An insulating film 28 of the same composition as that of the insulating layer 30 is formed on the insulating layer 33 and the third copper conductive layer 13.

The second and third copper conductive layers 10 and 13 in FIG. 3(b) are fabricated through so-called Dual-Damascene process. That is, the hole 8 and the trench 12 are formed in a continuous manner through etching and the barrier metal films 9 and 11 on the surfaces of the hole 8 and the trench 12 are formed at one time. Thereafter, the hole 8 and the trench 12 are filled with the copper conductive layers 10 and 13 at one time.

As described above, also in the semiconductor device of FIG. 3(b) having a similar construction of FIG. 3(a), diffusion of copper from all of the copper conductive layers 5, 10 and 13 can be prevented and an wiring capacitance can be reduced as compared with a prior art wiring structure of FIG. 4 so that a high speed operation of the semiconductor device is achieved.

Meanwhile, to form the insulating layers 31 and 32 continuously and afterward to form the copper conductive layers 10 and 13 through above Dual-Damascene process, i.e. at one time, is also possible.

While preferred embodiments of the present invention have been described, such descriptions are for illustrative purposes only, and it is to be understood that changes and variations can be made without departing from the sprit or scope of the present invention.

What is claimed is:

1. A semiconductor device comprising a first insulating layer having a first trench and formed on a semiconductor substrate, a first copper conductive layer formed so as to fill the first trench, a second insulating layer having a hole communicating with the first copper conductive layer, a second copper conductive layer filling the hole so as to contact with the first copper conductive layer, a third insulating layer being formed on the second insulating layer and having a trench communicating with the second copper conductive layer, and a third copper conductive layer contacting the second copper conductive layer and being formed so as to fill the trench formed in the third insulating layer,
wherein either the first insulating layer or the second insulating layer or the third insulating layer is made of a material containing boron nitride as a main component.

2. A semiconductor device comprising a first insulating layer having a first trench and formed on a semiconductor substrate, a first copper conductive layer formed so as to fill the first trench, an insulating film having a first hole communicating with the first copper conductive layer and with which the first copper conductive layer and the first insulating layer are coated, a second insulating layer having a second hole communicating with the first hole, a second copper conductive layer filling the first and second holes so as to contact with the first copper conductive layer, a third insulating layer being formed on the second insulating layer and having a trench communicating with the second copper conductive layer, and a third copper conductive layer contacting the second copper conductive layer and being formed so as to fill the trench formed in the third insulating layer,
wherein the insulating film is made of a material containing boron nitride as a main component.

3. A semiconductor device comprising a first insulating layer having a first trench and formed on a semiconductor substrate, a first copper conductive layer formed so as to fill the first trench, an insulating film having a first hole communicating with the first copper conductive layer and with which the first copper conductive layer and the first insulating layer are coated, a second insulating layer in which a second hole and a second trench communicating with the first hole are formed, a second copper conductive layer filling the second hole so as to contact with the first copper conductive layer, and a third copper conductive layer contacting with the second copper conductive layer and formed so as to fill the second trench formed in the second insulating layer,
wherein the insulating film is made of a material containing boron nitride as a main component.

4. The semiconductor device of claim 1, wherein the insulating layer made of a material containing boron nitride as a main component includes hydrogen.

5. The semiconductor device of claim 2, wherein the insulating film made of a material containing boron nitride as a main component includes hydrogen.

6. The semiconductor device of claim 3, wherein the insulating film made of a material containing boron nitride as a main component includes hydrogen.

7. The semiconductor device of claim 1, wherein the insulating layer made of a material containing boron nitride as a main component includes carbon or fluorine.

8. The semiconductor device of claim 2, wherein the insulating film made of a material containing boron nitride as a main component includes carbon or fluorine.

9. The semiconductor device of claim 3, wherein the insulating film made of a material containing boron nitride as a main component includes carbon or fluorine.

10. The semiconductor device of claim 1, wherein the insulating layer made of a material containing boron nitride as a main component is amorphous.

11. The semiconductor device of claim 2, wherein the insulating film made of a material containing boron nitride as a main component is amorphous.

12. The semiconductor device of claim 3, wherein the insulating film made of a material containing boron nitride as a main component is amorphous.

13. The semiconductor device of claim 1, wherein the insulating layer made of a material containing boron nitride as a main component is in a state of a mixture of microcrystals and an amorphous structure.

14. The semiconductor device of claim 2, wherein the insulating film made of a material containing boron nitride as a main component is in a state of a mixture of microcrystals and an amorphous structure.

15. The semiconductor device of claim 3, wherein the insulating film made of a material containing boron nitride as a main component is in a state of a mixture of microcrystals and an amorphous structure.
